(19) United States
(12) Patent Application Publication
(10) Pub. No.: US 2022/0302355 A1
(43) Pub. Date: Sep. 22, 2022

(54) MOUNTING BOARD AND ELECTRONIC DEVICE

(71) Applicant: KYOCERA Corporation, Kyoto-shi, Kyoto (JP)

(72) Inventor: Akihiko FUNAHASHI, Kyoto-shi (JP)

(73) Assignee: KYOCERA Corporation, Kyoto-shi, Kyoto (JP)

(21) Appl. No.: 17/638,100

(22) PCT Filed: Aug. 28, 2020
(86) PCT No.: PCT/JP2020/032597

§ 371 Date: Feb. 24, 2022

(30) Foreign Application Priority Data
Aug. 29, 2019 (JP) 2019-156959

(51) Int. Cl. H01L 33/48; H01L 31/0203; H01L 33/52; H01L 31/12

(52) U.S. Cl. CPC H01L 33/486; H01L 31/0203; H01L 33/52; H01L 31/12

(57) ABSTRACT

The mounting board includes a base portion and a frame portion. The base portion includes a first surface including a first mounting region. The frame portion includes a second surface including a second mounting region and an inner wall surface intersecting with the second surface, and the frame portion is located on the first surface to surround the first mounting region. The inner wall surface of the frame portion includes a first portion connecting with the second mounting region and a second portion located opposite to the first portion with the first mounting region interposed therebetween. The second portion includes an inclined surface that is inclined so as to move away from the first mounting region as it moves away from the first surface in a cross-sectional view.

### TECHNICAL FIELD

The present disclosure relates to a mounting board on which a light receiving and emitting element or the like is mounted and an electronic device.

### BACKGROUND ART

A mounting board on which a light receiving element and a light emitting element are mounted is known. (see WO 2017/203953). In such a mounting board, the light emitted by the light emitting element is reflected by a detection target and then received by the light receiving element to be detected.

Generally, in the mounting board including the light receiving element and the light emitting element, the light receiving element and the light emitting element may be mounted on an upper surface of a substrate and on the same flat surface. In this case, in order to prevent the light receiving element from directly receiving the light emitted by the light emitting element, a wall is provided with a housing or the like.

However, in recent years, downsizing of the mounting board has been required. Thus, a structure is conceivable in which a recessed portion is provided in the mounting board so as to narrow a space between the light receiving element and the light emitting element as much as possible, the light receiving element is mounted in the recessed portion, and the light emitting element is mounted on the recessed portion (front surface of the mounting board). However, with this structure, it is difficult to provide the wall with the housing or the like between the light receiving element and the light emitting element, and there is a concern that a portion of the light from the light emitting element is reflected by a side wall of the recessed portion, and the reflected light reaches the light receiving element. Thus, there has been a concern that the electronic device malfunctions. Further, there has been concern that deepening of the recessed portion in the mounting board in order to reduce the malfunction is an obstacle to downsizing of the electronic device.

### SUMMARY

A mounting board according to one aspect of the present disclosure includes a base portion and a frame portion. The base portion includes a first surface including a first mounting region. The frame portion includes a second surface including a second mounting region and an inner wall surface intersecting with the second surface, and the frame portion is located on the first surface of the base portion so as to surround the first mounting region. The inner wall surface of the frame portion includes a first portion connecting with the second mounting region and a second portion located opposite to the first portion with the first mounting region interposed therebetween. The second portion includes an inclined surface that is inclined so as to move away from the first mounting region as it moves away from the first surface of the base portion in a cross-sectional view.

An electronic device according to one aspect of the present disclosure includes a mounting board, a light receiving element mounted in a first mounting region, a light emitting element mounted in a second mounting region, and a housing including an opening portion above the light receiving element and covering the mounting board.

### BRIEF DESCRIPTION OF DRAWINGS

FIG. 1A is a top view illustrating the outer appearance of a mounting board and an electronic device according to a first embodiment of the present disclosure, and FIG. 1B is a vertical sectional view taken along line X1-X1 in FIG. 1A.

FIG. 2A is a top view illustrating an outer appearance of a mounting board and an electronic device according to another aspect of the first embodiment of the present disclosure, and FIG. 2B is a vertical cross-sectional view taken along line X2-X2 in FIG. 2A.

FIG. 3 is a vertical cross-sectional view illustrating a mounting board and an electronic device according to another aspect of the first embodiment of the present disclosure.

FIG. 4 is a vertical cross-sectional view illustrating a mounting board and an electronic device according to another aspect of the first embodiment of the present disclosure.

FIG. 5A is a top view illustrating the outer appearance of an electronic device according to another aspect of the first embodiment of the present disclosure, and FIG. 5B is a vertical cross-sectional view taken along line X5-X5 in FIG. 5A.

FIG. 6 is a vertical cross-sectional view illustrating a mounting board and an electronic device according to another aspect of the first embodiment of the present disclosure.

FIG. 7 is a vertical cross-sectional view illustrating a mounting board and an electronic device according to another aspect of the first embodiment of the present disclosure.

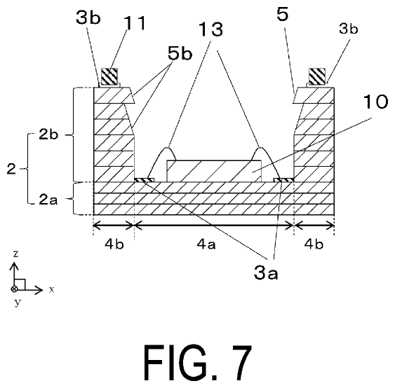

FIG. 8 is a vertical cross-sectional view illustrating a mounting board and an electronic device according to an aspect of a second embodiment of the present disclosure.

### DETAILED DESCRIPTION

### Configuration of Mounting Board and Electronic Device

Several exemplary embodiments of the present disclosure will be described hereinafter with reference to the drawings. In the following description, a configuration in which a light receiving element and a light emitting element are mounted on a mounting board, and the mounting board is covered with a housing is defined as an electronic device. Any direction may be defined as upward or downward for the mounting board and the electronic device, but for the sake of simplicity, an xyz orthogonal coordinate system is defined and a positive side in the z direction is defined as upward.

### First Embodiment

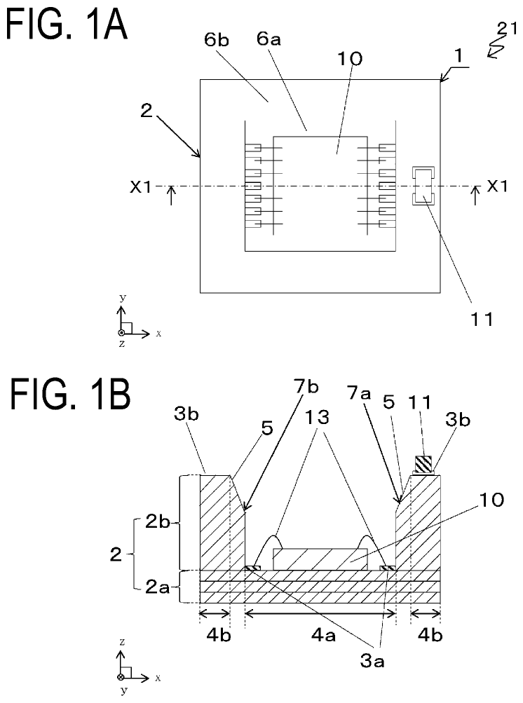

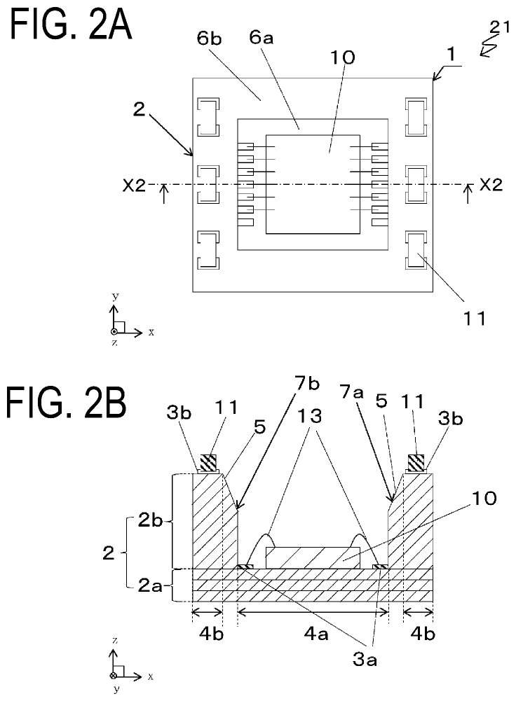

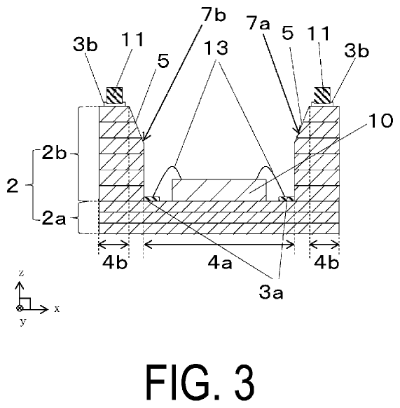

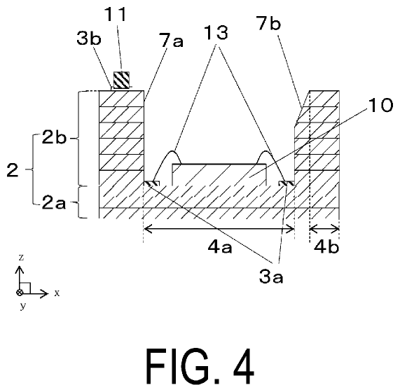

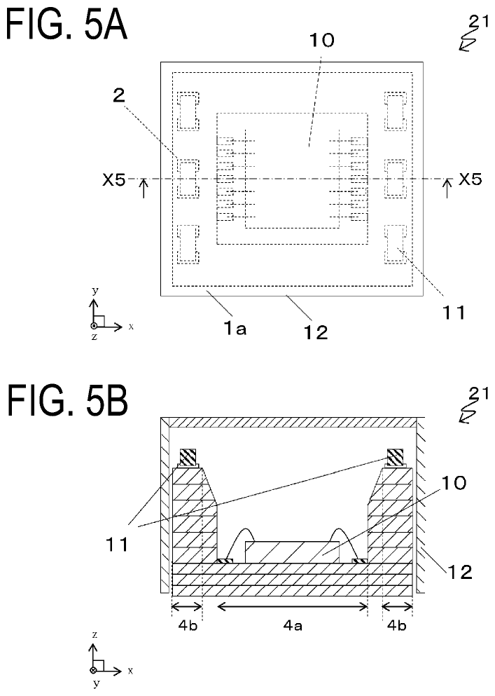

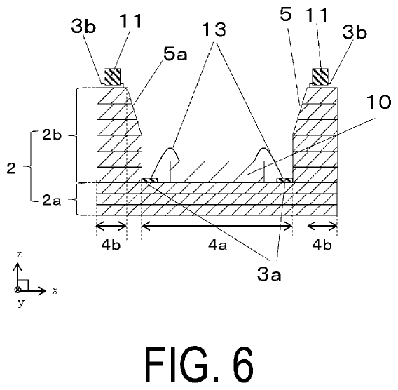

A mounting board 1 and an electronic device 21 provided with the mounting board 1 according to a first embodiment of the present disclosure will be described with reference to FIGS. 1 to 6. Note that FIG. 1, FIG. 2, FIG. 4, and FIG. 5 illustrate top views (views viewed in a direction toward the first surface and the second surface of the mounting board 1) and vertical cross-sectional views of the electronic device 21, and FIGS. 3 and 6 illustrate vertical cross-sectional views of the device. Note that a lid 12 is not illustrated in FIGS. 1 to 3.

The mounting board 1 includes a base portion 2a and a frame portion 2b. The base portion 2a includes a first surface 6a including a first mounting region 4a. The first mounting region 4a may include a first electrode pad 3a electrically connected to a light receiving element 10. The frame portion 2b includes a second surface 6b including a second mounting region 4b and an inner wall surface 7 intersecting with the second surface 6b. The frame portion 2b is located on the first surface 6a so as to surround the first mounting region 4a. Note that the first surface 6a is an upper surface of the base portion 2a in the drawing, and the second surface 6b is an upper surface of the frame portion 2b in the drawing. In the second mounting region 4b, at least one light emitting element is mounted, and at least one second electrode pad 3b electrically connected to the light emitting element is located. The frame portion 2b is located on the first surface 6a so as to surround the first mounting region 4a. The inner wall surface 7 of the frame portion 2b includes: a first portion 7a connecting with the second mounting region 4b; and a second portion 7b located opposite to the first portion 7a with the first mounting region 4a interposed therebetween. In other words, the first portion 7a includes, of the second surface 6b, a portion where the second mounting region 4b is located and a portion connecting to the second mounting region 4b. In this case, in a cross-sectional view, the second portion 7b includes an inclined surface 5 that is inclined so as to move away from the first mounting region 4a as it moves away from the first surface 6a.

The mounting board 1 includes the base portion 2a and the frame portion 2b. The base portion 2a includes the first mounting region 4a including the first electrode pad 3a electrically connected to the light receiving element 10 on the first surface 6a. In the frame portion 2b, at least one light emitting element is mounted on the second surface 6b, and the second surface 6b includes at least one second mounting region 4b on which at least one second electrode pad 3b electrically connected to the light emitting element is located. The first mounting region 4a is a region on which at least one or more light receiving elements 10 are mounted, and can be appropriately defined, for example, an inner side of the outermost periphery of the first electrode pad 3a, which will be described later, or an inner side of the frame portion 2b. Further, as a component mounted on the first mounting region 4a, an electronic component may be further mounted other than the light receiving element 10, and the number of the light receiving elements 10 and/or the electronic components is not specified. The second mounting region 4b is a region on which at least one or more light emitting elements 11 are mounted, and can be appropriately defined, for example, an inside of the outermost periphery of the second electrode pad 3b, which will be described later, or an inner portion of the frame portion 2b. Further, in this case, an electronic component other than the light emitting element 11 may be further mounted. Further, the number of the light emitting elements 11 and/or the electronic components is not specified.

The mounting board 1 includes the base portion 2a and the frame portion 2b. Here, a combination of the base portion 2a and the frame portion 2b is referred to as a substrate 2.

In the example illustrated in FIG. 3, the base portion 2a and the frame portion 2b are formed of a plurality of insulating layers. However, as illustrated in FIGS. 1 and 2. for example, a configuration formed of a mold, a configuration formed by pressing using a metal mold, or a configuration having only one insulating layer may be adopted. Examples of the material of the insulating layers forming the substrate 2 include an electrically insulating ceramic and a resin.

Examples of the electrically insulating ceramic used as the material of the insulating layers included in the substrate 2 include an aluminum oxide-based sintered body, a mullite-based sintered body, a silicon carbide-based sintered body, an aluminum nitride-based sintered body, a silicon nitride-based sintered body, and a glass ceramic sintered body. Examples of the resin used as the material of the insulating layers forming the substrate 2 include a thermoplastic resin, an epoxy resin, a polyimide resin, an acrylic resin, a phenol resin, a fluorine-based resin, and the like. Examples of the fluorine-based resin include an ethylene tetrafluoride resin.

The substrate 2 may be formed of nine insulating layers as illustrated in FIG. 3, or may be formed of eight or less or ten or more insulating layers. When the number of insulating layers is eight or less, the thickness of the mounting board 1 can be reduced. On the other hand, when the number of insulating layers is ten or more, the rigidity of the mounting board 1 can be increased. Further, an opening portion may be provided in each insulating layer, a stepped portion may be formed on an upper surface of the provided opening portion having a different size, and the first electrode pad 3a and other electrodes described below may be provided in the stepped portion.

For example, one side of an outermost periphery of the mounting board 1 may have a size of from 0.3 mm to 10 cm, and when the mounting board 1 has a quadrilateral shape in a plan view, the shape may be square or rectangular. Further, for example, the thickness of the mounting board 1 may be 0.2 mm or more.

An external circuit connection electrode may be provided on the side surface or the lower surface of the base portion 2a and the second surface 6b or the side surface. The external circuit connection electrode may electrically connect the mounting board 1 to an external circuit board or the electronic device 21 to an external circuit board.

Further, in addition to the first electrode pad 3a, the second electrode pad 3b and/or the external circuit connection electrode, electrodes formed between insulating layers, internal wiring electrical conductors, and internal through-hole conductors vertically connecting the internal wiring electrical conductors to each other may be provided on the first surface 6a or lower surface of the substrate 2. These electrodes, internal wiring electrical conductors, or internal through-hole conductors may be exposed on the surface of the substrate 2. The first electrode pad 3a, the second electrode pad 3b, and/or the external circuit connection electrode may each be electrically connected by the electrodes, the internal wiring electrical conductors, or the internal through-hole conductors.

When the substrate 2 is made of an electrically insulating ceramic, the first electrode pad 3a, the second electrode pad 3b, the external circuit connection electrode, the electrodes, the internal wiring electrical conductors, and/or the internal through-hole conductors contain tungsten (W), molybdenum (Mo), manganese (Mn), palladium (Pd), silver (Ag), or copper (Cu), or an alloy containing at least one metal material selected from these metals, or the like. Further, those may contain only copper (Cu). When the substrate 2 is made of a resin, the first electrode pad 3a, the second electrode pad 3b, the external circuit connection electrode, the internal wiring electrical conductors, and/or the internal through-hole conductors contain copper (Cu), gold (Au), aluminum (Al), nickel (Ni), molybdenum (Mo), palladium (Pd), or titanium (Ti), or an alloy containing at least one metal material selected from these metals, or the like.

A plated layer may be further provided on the exposed surface of the first electrode pad 3a, the second electrode pad 3b, the external circuit connection electrode, the electrodes, the internal wiring electrical conductor, and/or the internal through-hole conductor. According to this configuration, oxidation can be suppressed by protecting the exposed surfaces of the external circuit connection electrode, the electrical conductor layer, and the through-hole conductors. Further, according to this configuration, the first electrode pad 3a and the light receiving element 10 can be favorably electrically connected via an electronic element bonding member 13 such as wire bonding. The plated layer may be formed by depositing a nickel (Ni) plated layer having a thickness of from 0.5 μm to 10 μm, or by sequentially depositing the nickel plated layer and a gold (Au) plated layer having a thickness of from 0.5 μm to 3 μm.

The frame portion 2b is on the first surface 6a and is located so as to surround the first mounting region 4a. In other words, the substrate 2 includes the recessed portion between the frame portion 2b and the base portion 2a, and the light receiving element 10 mounted in the first mounting region 4a is mounted the inner side of the recessed portion.

In a cross-sectional view, the first portion 7a connected with the second mounting region 4b of the frame portion 2b of the mounting board 1 and the second portion 7b located opposite to the first portion 7a with the first mounting region 4a interposed therebetween each includes the inclined surface 5 that is inclined so as to move away from the first mounting surface 6a as it moves away from the first mounting region 4a. The inclined surface 5 may be located connected with the second surface 6b. This makes it possible to reflect light from the light emitting element 11 so as to be less likely to enter the light receiving element 10 while widening the entrance of an opening.

Generally, in recent years, downsizing of the electronic devices has been required. In response to this, a structure is conceivable in which the recessed portion is provided in the mounting board so as to narrow a space between the light receiving element and the light emitting element as much as possible, the light receiving element is mounted in the recessed portion, and the light emitting element is mounted on the recessed portion (surface of the mounting board). However, with this structure, it is difficult to provide the wall with the housing or the like between the light receiving element and the light emitting element, and there is a concern that a portion of the light from the light emitting element is reflected by a side wall of the recessed portion, and the reflected light reaches the light receiving element. Thus, there has been a concern that an electronic device malfunctions. Further, there has been concern that deepening of the recessed portion in the mounting board in order to prevent the malfunction is an obstacle to downsizing of the electronic device.

In response to this, in the present embodiment, the frame portion 2b includes the inclined surface 5 as described above. Accordingly, even in a case where a portion of the light from the light emitting element 11 is reflected by the second portion 7b which is the inner wall surface 7 of the frame portion 2b, it is possible to reduce the reflection of the light to the light receiving element 10. Thus, it is possible to reduce the possibility of the light reflected by the inner wall surface 7 of the frame portion 2b reaching the light receiving element 10 and the electronic device 21 malfunctioning. Further, since it is possible to reduce the malfunction of the electronic device 21 without providing a wall with the lid 12 between the light emitting element 11 and the light receiving element 10, the electronic device 21 can be downsized.

The inclined surface 5 is located in the second portion 7b located opposite to the first portion 7a with the first mounting region 4a interposed therebetween. In other words, the inclined surface 5 is located opposite to the inner wall where the second mounting region 4b is located. There may be a plurality of the second mounting regions 4b, and in this case, similarly there may be a plurality of the inclined surfaces 5. For example, in a case where the mounting board 1 has a rectangular shape, the second mounting regions 4b may be located at four sides, and in this case, the inclined surfaces 5, may be located on all of the inner walls of the frame portion 2b, in other words, the inclined surfaces 5 may be located on an entire circumference of the inner wall surface 7. Further, even in a case where the second mounting region 4b is one surface, there may be the plurality of inclined surfaces 5. In other words, the number of the inclined surface 5 may be equal to or greater than the number of the second mounting regions 4b.

The frame portion 2b may be molding processed, for example, such as a mold as in the examples illustrated in FIGS. 1 and 2, or may be composed of a plurality of insulating layers as in the examples illustrated in FIGS. 3 to 5.

The frame portion 2b is molding processed, for example, such as the mold as in the examples illustrated in FIGS. 1 and 2, so that it is possible to improve the accuracy of the angle of the inclined surface 5. Thus, the effect of the present embodiment can be achieved in a state close to a design value, and influence of a manufacturing error and the like can be reduced. Further, the frame portion 2b is molding processed such as the mold, so that it is possible to reduce the roughness of the surface of the inclined surface 5. Thus, when the light from the light emitting element 11 is reflected at the surface of the inclined surface 5, it is possible to reduce irregular reflection, and the effect of the present embodiment can be improved.

In a case where the frame portion 2b includes the plurality of insulating layers as in the examples illustrated in FIGS. 3 to 6, an internal wiring can be provided between the layers in the frame portion 2b. Thus, the wiring of the mounting board 1 can have a degree of freedom, and electrical characteristics of the electronic device 21 can be improved. Further, the frame portion 2b is the plurality of insulating layers, so that the thickness of the frame portion 2b can be easily changed by the thickness and/or the number of layers of the insulating layer. Thus, it is possible to more appropriately design and produce the height of the frame portion 2b under conditions such as the position of the light emitting element 11.

In a case where the frame portion 2b includes the plurality of insulating layers as in the examples illustrated in FIGS. 3, 4, and 6, the inclined surface 5 may be provided on a part of the insulating layers of the frame portion 2b in a cross-sectional view as in the examples illustrated in FIGS. 3 and 4, or may be provided on all layers of the insulating layers of the frame portion 2b in a cross-sectional view. In either case, the effect of the present embodiment can be obtained.

When the frame portion 2b is layered with the plurality of layers, a first layer 8a, which is the uppermost layer, of the plurality of layers may include the inclined surface 5. According to this configuration, the second mounting region can be ensured without increasing the size of the electronic element mounting substrate 1 even when the inclined surface 5 is located in the frame portion 2b, and the effect of the present embodiment can be achieved.

When the frame portion 2b is layered with the plurality of layers, the inclined surface 5 may be continuously located on the plurality of layers. According to this configuration, the region of the inclined surface 5 can be widened, and the effect of the present embodiment can be improved.

The height of the frame portion 2b has a height at which the light receiving element is housed within the frame portion 2b. The frame portion 2b has the height at which the light receiving element is housed within the frame portion 2b, so that the effect of the present embodiment can be achieved. Further, the height of the frame portion 2b is greater than the height of the light receiving element, so that it is possible to reduce the possibility that the light receiving element picks up the light from the outside.

The inclined surface 5 of the frame portion 2b may be located on the entire circumference of the inner wall surface 7. Accordingly, even in a case where the light from the light emitting element 11 reaches a portion other than the opposing surface side, when a portion of the light is reflected at the inner wall surface 7 of the frame portion 2b, it is possible to reduce the reflection of the light to the light receiving element 10. Thus, it is possible to reduce the possibility of the light reflected by the inner wall surface 7 of the frame portion 2b reaching the light receiving element 10 and the electronic device 21 malfunctioning.

The inclination angle of the inclined surface 5 of the mounting board 1 may be from 30° to 60° with respect to the first mounting region 4a. The angle of the inclined surface 5 is from 30° to 60° with respect to the first mounting region 4a, so that it is possible to have the effect of reflecting the light to the information side of the frame portion 2b as compared when the light from the light emitting element 11 reaches the inclined surface 5. Further, it is easy to ensure the second mounting region 4b where the light emitting element 11 is mounted on the second surface 6b. Thus, the effect of the present embodiment can be achieved, and it is possible to reduce an obstacle to downsizing of the electronic device 21.

The base portion 2a and the frame portion 2b may be composed of a ceramic material as a main component, and the ceramic material may be black in this case. The base portion 2a and the frame portion 2b are composed of the ceramic material as the main component, so that it possible to process the frame portion 2b by punching with a metal mold or the like. Thus, it is possible to reduce the occurrence of dusts from the frame portion 2b. Thus, it is possible to reduce the possibility that the dusts stick to the surface of the light receiving element 10 to generate a noise. Further, it is possible to reduce the roughness of the surface of the inner wall surface 7 of the frame portion 2b. Accordingly, even in a case where the light generated from the light emitting element 11 reaches the inner wall surface 7 of the frame portion 2b, it is possible to reduce the possibility that the light is irregularly reflected to reach the light receiving element 10. Further, the ceramic material is black, so that it is possible to reduce the possibility of the light being reflected when the light generated from the light emitting element 11 reaches the inner wall surface 7 of the frame portion 2b. Thus the effect of the present embodiment can be achieved.

The base portion 2a and the frame portion 2b may be composed of a resin material as a main component. As a result, the frame portion 2b can be manufactured by a molding process such as a mold, and the effects described above can be achieved in this case. Further, the resin material can reduce a glass component included in the frame portion 2b. Thus, it is possible to reduce the generation of the reflection of the light at the inner wall surface 7 of the frame portion 2b. Thus, it is possible to improve the effect of the present embodiment.

The inclined surface 5 may be located continuously from the second surface 6b to the lower surface in a cross-sectional view, or may be located up to a middle portion of the frame portion 2b in a cross-sectional view. In this case, in a case where the frame portion 2b includes a plurality of layers, the inclined surface 5 may be located across the plurality of layers. Further, in this case, the inclined surface 5 may include a first inclined surface 5a located across at least two or more layers of the plurality of layers. Further, the inclined surface 5 may include a plurality of second inclined surfaces 5b each located in at least two layers of the plurality of layers. The inclined surface 5 is located across the plurality of layers, so that even in a case where the light from the light emitting element 11 reaches any portion of the inner wall surface 7 of the frame portion 2b, it is possible to reduce the possibility that the reflected light reaches the light receiving element 10. In particular, the inclined surface 5 is located continuously from the second surface 6b to the lower surface in a cross-sectional view, so that even in a case where the light from the light emitting element 11 reaches any portion of the inner wall surface 7 of the frame portion 2b, it is possible to reduce the possibility that the reflected light reaches the light receiving element 10. Further, the inclined surface 5 is located up to a middle portion of the frame portion 2b in a cross-sectional view, so that it is possible to reduce the frame portion 2b becoming large in size, while the mounting region of the light emitting element 11 is ensured in the second surface 6b.

### Configuration of Electronic Device

An example of the electronic device 21 is illustrated in FIGS. 1 to 5. The electronic device 21 includes the mounting board 1, the light receiving element 10 mounted in the first mounting region 4a of the mounting board 1, the light emitting element 11 mounted in the second mounting region 4b, and the lid 12 located on a third surface 1a of the mounting board 1. Note that the third surface 1a is the upper surface of the mounting board 1 in the drawing.

The electronic device 21 includes the mounting board 1, the light receiving element 10 mounted in the first mounting region 4a, and the light emitting element 11 mounted in the second mounting region 4b. An example of the light receiving element 10 is, for example, a reflective CMOS sensor or a PD sensor. An example of the light emitting element 11 is a Light Emitting Diode (LED) or a VCSEL element. The light receiving element 10 and the mounting board 1, and the light emitting element 11 and the mounting board 1 may be electrically connected to each other by, for example, the electronic element bonding member 13. The electronic device 21 includes the lid 12 covering the mounting board 1. The lid 12 may have a shape in which a housing made of a metal or a resin as a material and a plate-like transparent member made of a resin or a glass material as a material are combined as in the example illustrated in FIG. 3-5B, or may have a flat plate shape such as a glass plate. The lid 12 has a shape in which the housing and the plate material are combined, so that it is possible to further improve airtightness or reduce the direct application of stress from the outside to the electronic device 21. The lid 12 is made of, for example, the resin or the metal material. Further, the lid 12 may have a transparent lid formed of a resin, a liquid, a glass, a crystal, or the like and located on the upper surface. Further, the lid 12 may be electrically connected to a pad or the like located on the surface of the mounting board 1 via a bonding member such as solder.

Note that the lid 12, when viewed from directly above, may be provided with an opening portion on at least one side in any of four directions or on the lower surface side. Further, an external circuit board may be inserted through the opening portion of the lid 12 and electrically connected to the mounting board 1. Further, after the external circuit board has been electrically connected to the mounting board 1, the opening portion of the lid 12 may be sealed with a sealing material such as a resin or the like, such that the inner portion of the electronic device 21 may be hermetically sealed.

The electronic device 21 includes the mounting board 1 illustrated in the present embodiment, so that a space between the light receiving element 10 and the light emitting element 11 can be made smaller in a plan view, and the electronic device 21 can be downsized.

In the electronic device 21, in a cross-sectional view, an upper end of the light receiving element 10 is located below a lower end of the light emitting element 11. Accordingly, even in a case where a portion of the light from the light emitting element 11 is reflected by the inner wall surface 7 of the frame portion 2b, it is possible to further reduce the reflection of the light to the light receiving element 10. Therefore, it is possible to further improve the effect of the present embodiment. Further, the inclined surface 5 may be located above an upper end of the light receiving element 10. Accordingly, since the inclined surface 5 is located at a location on which the light from the light emitting element 11 is more likely to be incident, even in a case where a portion of the light from the light emitting element 11 is reflected by the inner wall surface 7 of the frame portion 2b, it is possible to further reduce the reflection of the light to the light receiving element 10.

In a cross-sectional view, in the electronic device 21, the second surface 6b, in particular, the inner end of the second surface 6b may be located above an imaginary line A connecting the center of the light receiving element 10 and the center of the light emitting element 11. Accordingly, even in a case where a portion of the light from the light emitting element 11 is reflected by the inner wall surface 7 of the frame portion 2b, it is possible to further reduce the reflection of the light to the light receiving element 10. Therefore, it is possible to further improve the effect of the present embodiment.

### Method of Manufacturing Mounting Board and Electronic Device

Next, an example of a method of manufacturing the mounting board 1 and the electronic device 21 according to the present embodiment will be described. Note that as the example of the manufacturing method, a method of manufacturing the substrate 2 using a multipiece wiring board will be described below.

(1) First, ceramic green sheets that form the substrate 2 (the base portion 2a and the frame portion 2b) are formed. For example, in order to obtain the substrate 2 made of an aluminum oxide (Al₂O₃)-based sintered body, a powder of, for example, silica (SiO₂), magnesia (MgO), or calcia (CaO) is added as a sintering aid to Al₂O₃ powder. Further, a suitable binder, a solvent, and a plasticizer are added, and then a mixture thereof is kneaded to form a slurry. Then, multipiece ceramic green sheets are obtained by a formation method, such as a doctor blade method or a calender roll method.

Note that when the substrate 2 is made of a resin, for example, the substrate 2 can be formed by a transfer molding method, an injection molding method, pressing with a metal mold, or the like, using a metal mold capable of forming the resin into a predetermined shape. Further, the material of the substrate 2 may be a base material made of glass fibers impregnated with a resin, such as a glass epoxy resin. In this case, the substrate 2 can be formed by impregnating a base material made of glass fibers with an epoxy resin precursor and thermally curing the epoxy resin precursor at a predetermined temperature.

(2) Next, a metal paste is applied to or caused to fill portions of the ceramic green sheets obtained in the above step (1), that are expected to serve as the first electrode pad 3a, the external circuit connection electrode, the internal wiring electrical conductors, and the through-hole conductors by using a screen printing method or the like. This metal paste is created so as to have appropriate viscosity by adding a suitable solvent and binder to the metal powder formed of the above-described metal materials, and kneading the mixture. Note that a glass or ceramics may also be included in the metal paste in order to increase the bonding strength with the substrate 2.

Further, when the substrate 2 is made of a resin, the first electrode pad 3a, the external circuit connection electrode, the internal wiring electrical conductors, and the through-hole conductors can be manufactured by sputtering, vaporizing, or the like. Furthermore, those may be manufactured by using a plating method after providing a metal film on the surface.

(3) Next, the aforementioned green sheet is processed using a metal mold or the like. Here, when the substrate 2 has an opening portion, a cutout section or the like, the opening portion, the cutout section or the like may be formed at a predetermined portion of the green sheet to be the substrate 2.

Note that in this step, the inclined surface 5 may be formed in the ceramic green sheet to be the frame portion 2b. As a method of forming the inclined surface 5, for example, an inclined surface may be formed in the ceramic green sheet so as to form the inclined surface 5 by using a metal mold or the like to the insulating layers.

(4) Subsequently, the ceramic green sheets to be respective insulating layers of the substrate 2 are layered and placed under pressure. In this way, the ceramic green sheets to be insulating layers may be layered to produce a ceramic green sheet laminated body to be the substrate 2 (the mounting board 1). Further, in this case, an opening portion of the frame portion 2b may be provided at predetermined positions by using a metal mold, a punching, a laser, or the like, in the ceramic green sheet in which the plurality of layers are layered. Further, a portion to be the inclined surface 5 after the layering may be formed. In a case where the inclined surface 5 is located from the second surface 6b up to the middle of the frame portion 2b in a cross-sectional view, the inclined surface 5 can be manufactured by: layering a ceramic green sheet or a ceramic green sheet laminated body punched out by a metal mold having a larger concave shape as described above or by a metal mold having an inclined surface; and a ceramic green sheet laminated body punched out in a normal metal mold.

(5) Subsequently, the ceramic green sheet laminated body is fired at a temperature of from approximately 1500° C. to approximately 1800° C. to obtain the multipiece wiring board in which a plurality of the substrates 2 (the mounting boards 1) are arrayed. Note that, in this step, the above-described metal paste is fired at the same time as the ceramic green sheets forming the substrate 2 (the mounting board 1), and forms the first electrode pad 3a, the external circuit connection electrode, the internal wiring electrical conductor, and the through-hole conductor.

(6) Next, the multipiece wiring board obtained by the firing is divided into the plurality of substrates 2 (mounting boards 1). In this division, a method can be used in which split grooves are formed in the multipiece wiring board in locations that will serve as the outer edges of the substrates 2 (mounting boards 1), and the multipiece wiring board is then divided along those split grooves. Alternatively, a method can be used in which the multipiece wiring board is cut, by slicing and the like, along the locations that will serve as the outer edges of the substrates 2 (mounting boards 1). Note that the split grooves can be formed by using a slicing device to cut to a depth less than the thickness of the multi-piece wiring substrate after firing. Also, the split grooves can be formed by pressing a cutter blade against the ceramic green sheet laminated body used as the multipiece wiring board, or by using a slicing device to form cuts having a depth less than the thickness of the ceramic green sheet laminated body. Note that, before or after dividing the multipiece wiring board described above into the plurality of substrates 2 (mounting boards 1), the plating may be applied to the first electrode pad 3a, the external connection pad, and the exposed wiring conductors using an electrolytic or electroless plating method, respectively.

(7) Next, the light receiving element 10 and the light emitting element 11 of the mounting board 1 are mounted in the first mounting region 4a and in the second mounting region 4b, respectively. The light receiving element 10 is electrically bonded to the mounting board 1 by the electronic element bonding member 13 such as wire bonding or the like. In this case, an adhesive or the like may be provided on the light receiving element 10 or the mounting board 1 to fix the light receiving element 10 to the mounting board 1. Further, after the light receiving element 10 and the light emitting element 11 are mounted on the mounting board 1, the lid 12 may be bonded to the mounting board 1.

The electronic device 21 can be manufactured by manufacturing the mounting board 1 as described in steps (1) to (7) and mounting the light receiving element 10 and the light emitting element 11 on the mounting board 1. Note that the order of the above-described steps (1) to (7) can be changed to another order in which the process can be performed.

### Second Embodiment

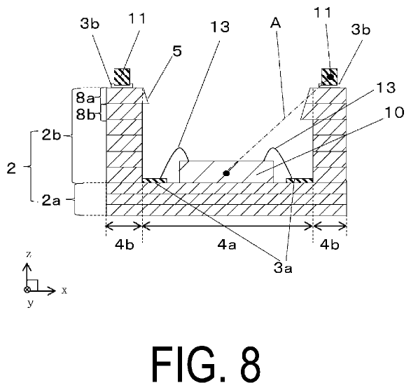

The mounting board 1 according to a second embodiment of the present disclosure will be described next with reference to FIG. 8.

The mounting board 1 according to the present embodiment differs from the mounting board 1 according to the first embodiment in that the frame portion 2b is layered with a plurality of layers, and the uppermost layer of the plurality of layers protrudes toward the first mounting region 4a side, which is an inner side, than the second layer from the top. In other words, a distance between the first portion 7a and the second portion 7b of the uppermost layer is closer than that of the second layer from the top.

In the example illustrated in FIG. 8, the frame portion 2b is layered with the plurality of layers, and the plurality of layers include the first layer 8a and a second layer 8b in order from the second surface 6b. In this case, in a cross-sectional view, the first layer 8a protrudes to the inner side than the second layer 8b. In other words, the distance between the first portion 7a and the second portion 7b of the first layer 8a is closer than that of the second layer 8b. Even in such a configuration, in a case where a portion of the light from the light emitting element 11 is reflected by the inner wall surface 7 of the frame portion 2b, it is possible to reduce the reflection of the light to the light receiving element 10. Thus, it is possible to reduce the possibility of the light reflected by the inner wall surface 7 of the frame portion 2b reaching the light receiving element 10 and the electronic device 21 malfunctioning. Further, since it is possible to reduce the malfunction of the electronic device 21 without providing a wall with the lid 12 between the light emitting element 11 and the light receiving element 10, the electronic device 21 can be downsized.

Further, the second layer 8b and layers on the lower surface thereof may also include inclined surfaces 5. As a result, even in a case where the light from the light emitting element 11 reaches the second layer from the top and the layers on the lower surface thereof, the second and the lower layers are located on the outer side, so that in a case where the light reflected by the inner wall surface 7 of the frame portion 2b, it is possible to reduce the possibility of the light reaching the light receiving element 10. Thus, it is possible to improve the effect of the present embodiment. Further, the uppermost layer protrudes to the inner side, so that the mounting region of the light emitting element 11 can be ensured, and it is possible to reduce the entry of the light from the light emitting element 11 into the inner side of the frame portion 2b.

Further, as in the example illustrated in FIG. 8, the layer having the inclined surface 5 protrudes to the inner side than the other layers, so that the side wall of the frame portion 2b easily shifts to the outside, in other words, a space is easily ensured. Accordingly, it is possible to reduce the possibility that the light from the light emitting element 11 reaches the frame portion 2b. Further, the side wall of the frame portion 2b shifts to the outside, so that it is possible to increase the distance between the light receiving element 10 and the side wall of the frame portion 2b. Thus, even in a case where the reflection of the light occurs when the light from the light emitting element 11 reaches a portion other than the inclined surface 5, it is possible to reduce the possibility of the reflected light reaching the light receiving element 10. Thus, it is possible to improve the effect of the present embodiment.

Further, as in the example illustrated in FIG. 8, the layer having the inclined surface 5 protrudes more to the inner side than the other layers, so that the first mounting region 4a of the light receiving element 10 can be widened. Thus, the electronic device 21 can be downsized.

The present disclosure is not limited to the above-described embodiments, and various modifications can be made to numerical values and the like. Further, for example, in the examples illustrated in the respective figures, the first electrode pad 3a and the second electrode pad 3b have a rectangular shape in a top view, but may be circular or have another polygonal shape. The arrangement, number, and shape of the first electrode pad 3a and the second electrode pad 3b, the mounting method of the electronic element, and the like in the above-described embodiments are not specified. Note that various combinations of characteristic portions of the above-described embodiments are not limited to the examples in the above-described embodiments. Further, the combinations of the respective embodiments are also possible.

### REFERENCE SIGNS LIST

1 Mounting board
1a Third surface
2 Substrate
2a Base portion
2b Frame portion
3a First electrode pad
3b Second electrode pad
4a First mounting region
4b Second mounting region
5 Inclined surface
5a First inclined surface
5b Second inclined surface
6a First surface (upper surface of base portion)
6b Second surface (upper surface of frame portion)
7 Inner wall surface
7a First portion
7b Second portion
8a First layer
8b Second layer
10 Light receiving element
11 Light emitting element
12 Lid
13 Electronic element bonding member
21 Electronic device
A Virtual line

1. A mounting board comprising:
a base portion comprising a first surface comprising a first mounting region;
a frame portion comprising a second surface comprising a second mounting region and an inner wall surface intersecting with the second surface and located on the first surface to surround the first mounting region,
wherein the inner wall surface of the frame portion includes a first portion connecting with the second mounting region, and a second portion located opposite to the first portion with the first mounting region interposed therebetween, and
in a cross-sectional view, the second portion includes an inclined surface that is inclined to move away from the first mounting region as it moves away from the first surface.

2. The mounting board according to claim 1,
wherein the inclined surface is located to connect with the second surface.

3. The mounting board according to claim 1,
wherein the frame portion comprises a plurality of layered layers, and
the inclined surface is located in at least one layer of the plurality of layers.

4. The mounting board according to claim 3,
wherein the inclined surface comprises a first inclined surface located across at least two or more layers of the plurality of layers.

5. The mounting board according to claim 3,
wherein the inclined surface comprises a plurality of second inclined surfaces each located in at least two layers of the plurality of layers.

6. The mounting board according to claim 1,
wherein the frame portion comprises a plurality of layered layers,
the plurality of layers comprises a first layer and a second layer in order from the second surface, and
in a cross-sectional view, a distance between the first portion and the second portion of the first layer is closer than that of the second layer.

7. The mounting board according to claim 6,
wherein the inclined surface is located in the first layer.

8. The mounting board according to claim 7,
wherein the inclined surface is located across the first layer and the second layer.

9. The mounting board according to claim 1,
wherein an inclination angle of the inclined surface with respect to the first mounting region is from 30° to 60°.

10. The mounting board according to claim 1,
wherein the frame portion and the base portion are composed of a ceramic material as a main component.

11. The mounting board according to claim 10,
wherein the ceramic material is black.

12. The mounting board according to claim 1,
wherein the frame portion and the base portion are composed of a resin material as a main component.

13. The mounting board according to claim 1,
wherein the inclined surface is located on the first portion and the second portion of the inner wall surface.

14. The mounting board according to claim 1,
wherein the inclined surface is located on an entire circumference of the inner wall surface.

15. An electronic device comprising:
the mounting board according to claim 1;
a light receiving element mounted in the first mounting region;
a light emitting element mounted in the second mounting region; and
a lid comprising an opening portion located above the light receiving element and located on a third surface of the mounting board.

16. The electronic device according to claim 15,
wherein, in a cross-sectional view, an upper end of the light receiving element is located below a lower end of the light emitting element.

17. The electronic device according to claim 15,
wherein, in a cross-sectional view, the second surface is located above an imaginary line connecting a center of the light receiving element and a center of the light emitting element.

18. The electronic device according to claim 15,
wherein the inclined surface is located above the upper end of the light receiving element.
